(19) United States
(12) Patent Application Publication
(10) Pub. No.: US 2015/0329969 A1
(43) Pub. Date: Nov. 19, 2015

(54) UNIFORMITY AND SELECTIVITY OF LOW GAS FLOW VELOCITY PROCESSES IN A CROSS FLOW EPITAXY CHAMBER WITH THE USE OF ALTERNATIVE HIGHLY REACTIVE PRECURSORS THOUGH AN ALTERNATIVE PATH

(71) Applicant: Applied Materials, Inc., Santa Clara, CA (US)

(72) Inventors: Zuoming ZHU, Sunnyvale, CA (US); Kuan Chien SHEN, Sunnyvale, CA (US); Balasubramanian RAMACHANDRAN, Santa Clara, CA (US)

(21) Appl. No.: 14/276,979

(22) Filed: May 13, 2014

(51) Int. Cl. C23C 16/56; C23C 16/455; C23C 16/24

(52) U.S. Cl. CPC C23C 16/56; C23C 16/24; C23C 16/455

(57) ABSTRACT

Methods for increasing layer uniformity in cross flow layer deposition are described herein. A method of depositing a layer can include delivering a deposition gas to a processing surface of a substrate using the deposition gas delivered through a first port in a first direction, depositing a layer on the processing surface of the substrate, the layer having one or more non-uniformities, and delivering a reactant gas to the layer through a second port in a second direction, the second direction being different from the first direction, the second direction and the first direction forming an azimuthal angle between them with respect to a central axis of the substrate support being up to about 145 degrees, the reactant gas reacting with the layer to diminish at least one of the one or more non-uniformities. The reactant gas can be delivered concurrent with or subsequent to the deposition gas.

### BACKGROUND

1. Field

Embodiments disclosed herein generally relate to methods for processing a substrate. More specifically, embodiments generally relate to reactive gas flow to control uniformity of a deposited layer and improve selectivity in selective deposition.

2. Description of the Related Art

In some processes, such as epitaxial deposition of a layer on a substrate, process gases may be flowed across a substrate surface in the same direction. For example, the one or more process gases may be flowed across a substrate surface between an inlet port and an exhaust port disposed on opposing ends of a process chamber to grow an epitaxial layer atop the substrate surface.

The current epitaxial chamber with cross flow introduces process gas lows into the chamber in two different directions using main inlet and cross flow inlet ports. The epitaxial deposition on the substrate is formed through the interaction of these two process gas flows. The process gases used in cross flow port are generally a subset of the process gases used in the main inlet port.

Undesirable thickness non-uniformities in epitaxial layers grown on a substrate surface may still exist while using conventional cross flow process gases. In particular, it has been observed that such non-uniformities in thickness may become even more undesirable for the cases of high pressure and/or low main carrier gas flows, because high pressure and low main carrier gas flows result in very low flow velocities and the resultant stagnant gases create specific non-uniform deposition on the substrate. In the specific example of high pressure SiP process, main carrier gas flow is as low as <7 slm and pressure is as high as 600 torr; the resultant uniformity pattern shows a very edge thick profile. Standard methods of tuning have not resulted in a uniform wafer profile. In addition, it has been observed that undesirable selectivity loss issue may still exist in selective deposition on a substrate surface while using conventional cross flow process gases.

Therefore, there is a need for improved methods for increasing uniformity in deposited layers and reducing selectivity loss in the case of selective deposition.

### SUMMARY

Embodiments disclosed herein generally relate to correcting non-uniformities in a deposited layer and improving selectivity in the case of selective deposition. In one embodiment, a method for depositing a layer can include delivering a deposition gas to a processing surface of a substrate, the substrate positioned on a substrate support in a process region of a process chamber, the deposition gas delivered through a first port in a first direction; depositing a layer on the processing surface of the substrate, the layer having one or more non-uniformities; and delivering a reactant gas to the layer through a second port in a second direction, the second direction being different from the first direction, the second direction and the first direction forming an azimuthal angle between them with respect to a central axis of the substrate support being up to about 145 degrees, the reactant gas reacting with the layer to diminish at least one of the one or more non-uniformities. In the case of selective deposition, the deposition gas is delivered through a first port in a first direction; depositing a layer on the desired surfaces/locations of the substrate but may cause undesired deposition on certain surfaces/locations of the substrate that require no deposition; and a reactant gas can be delivered to the substrate through a second port in a second direction, the second direction being different from the first direction, the second direction and the first direction forming an azimuthal angle between them with respect to a central axis of the substrate support being up to about 145 degrees, the reactant gas reacting with the substrate to remove undesired deposition on certain surfaces/locations of the substrate that require no deposition to improve selectivity.

In another embodiment, a method for depositing a layer can include flowing a deposition gas over a substrate from a first port positioned in a first direction; co-flowing a reactant gas concurrently with the deposition gas over the substrate from a second port positioned in a second direction, the second direction being different from the first direction, the second direction and the first direction forming an azimuthal angle between them with respect to a central axis of the substrate support being up to about 145 degrees; and depositing a layer on a surface of the substrate from a deposition product, wherein the deposition gas reacts to form the deposition product, and wherein the reactant gas increases the uniformity of the layer during the deposition without forming the deposition product; during the deposition, the reactant gas also can interact with the deposition gas and substrate preventing undesired deposition on certain surfaces/locations of the substrate that require no deposition to improve selectivity.

In another embodiment, a method for depositing a layer can include delivering a deposition gas comprising dichlorosilane, phosphine and hydrogen chloride (HCl) to a processing surface of a substrate, the substrate positioned on a substrate support in a process region of a process chamber, the deposition gas delivered through a first port in a first direction; depositing a silicon:phosphorus-containing layer on the processing surface of the substrate, the silicon-phosphorus containing layer having one or more non-uniformities; and delivering chlorine (Cl₂) to the silicon:phosphorus-containing layer formed on the substrate, the chlorine delivered through a second port in a second direction, the second direction and the first direction forming an azimuthal angle between them with respect to a central axis of the substrate support being between about 45 degrees and about 145 degrees, the chlorine reacting with the silicon:phosphorus-containing layer to diminish at least one of the one or more non-uniformities. On the other hand, the chlorine reacts with the substrate to remove undesired deposition on certain surfaces/locations of the substrate that require no deposition to improve selectivity.

In another embodiment, a method for depositing a layer can include flowing a deposition gas comprising dichlorosilane, phosphine and hydrogen chloride (HCl) over a substrate from a first port positioned in a first direction; co-flowing chlorine (Cl₂) concurrently over the substrate from a second port positioned in a second direction, the second direction being different from the first direction, the second direction and the first direction forming an azimuthal angle between them with respect to a central axis of the substrate support being up to about 145 degrees; and depositing a silicon:phosphorus-containing layer on a surface of the substrate from a deposition product, wherein the deposition gas reacts to form the deposition product, and wherein the chlorine gas increases the uniformity of the layer during the deposition through interacting with the deposition gas and affecting the deposition product distribution across the substrate; in the meanwhile, during the deposition, the chlorine gas also can interact with the deposition gas and substrate preventing undesired deposition on certain surfaces/locations of the substrate that require no deposition to improve selectivity.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a schematic side view of a process chamber useable with embodiments described herein;

FIG. 2 depicts a schematic top view of a process chamber useable with embodiments described herein;

FIG. 3 is a flow diagram of a method of depositing a layer, according to some embodiments described herein; and

FIG. 4 is a flow diagram of a method of depositing a layer, according to some embodiments described herein; and

FIG. 5 is a graph depicting improved layer uniformity of silicon:phosphorus-containing layers deposited according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Disclosed herein are methods for improving uniformity of film deposition and improving selectivity in selective deposition with the use of reactive gas flow through alternative gas flow injection path. Such reactive gas can be introduced sequentially, e.g. after the main deposition gases stop, or simultaneously with the main deposition gases by controlling the partial pressures and dilutions of these reactive gases. It has been observed that undesirable thickness non-uniformities in epitaxial layers grown on a substrate surface may still exist while using conventional cross flow process gases. In particular, the inventors have observed that such non-uniformities in thickness may become even more undesirable for the cases of high pressure and/or low main carrier gas flows. In addition, the inventors have observed that undesirable selectivity loss issue may still exist in selective deposition on a substrate surface while using conventional cross flow process gases. Embodiments disclosed herein may advantageously overcome thickness non-uniformities in deposited layers. The embodiments may also further improve selectivity in selective deposition. Embodiments are more clearly described with reference to the figures below.

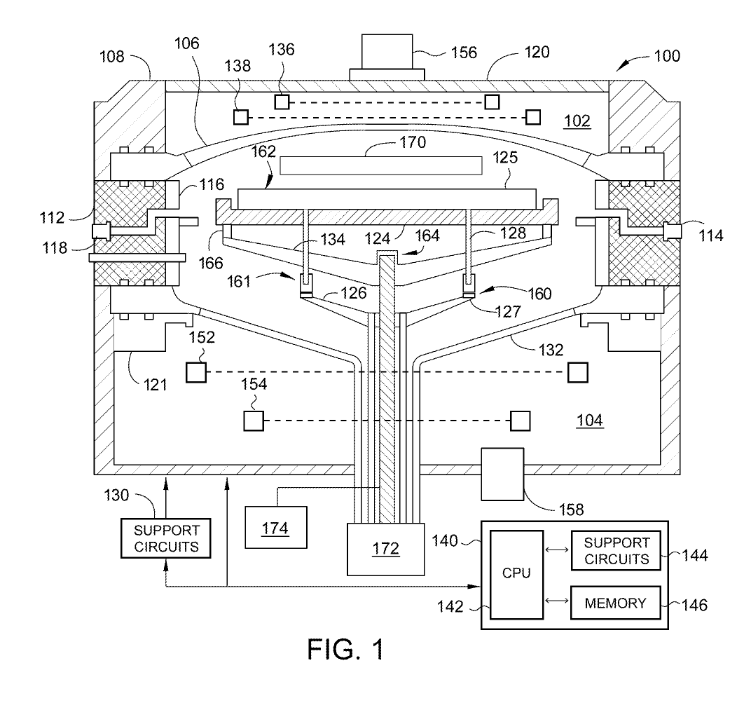

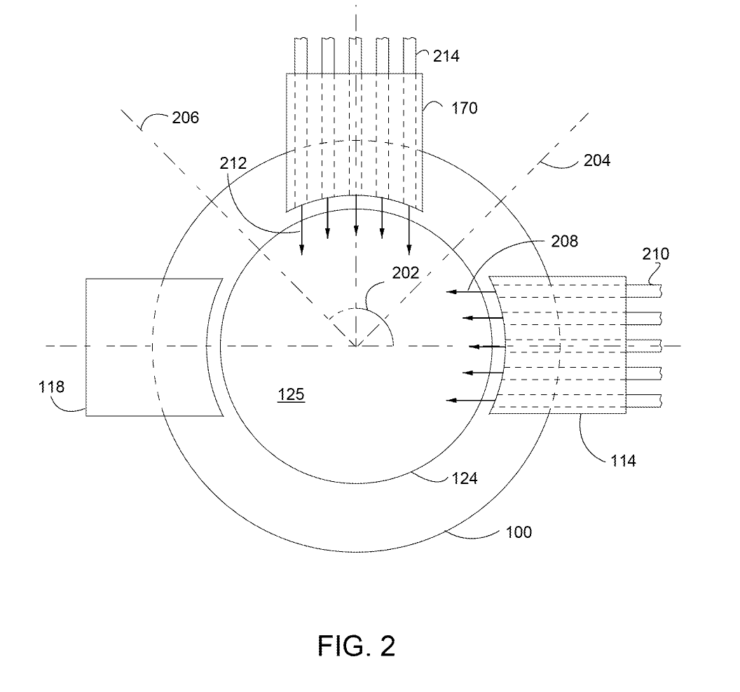

FIG. 1 depicts a schematic side view of a process chamber 100, according to one embodiment. The process chamber 100 may be modified from a commercially available process chamber, such as the RP EPI® reactor, available from Applied Materials, Inc. of Santa Clara, Calif., or any suitable semiconductor process chamber adapted for performing epitaxial silicon deposition processes. The process chamber 100 may be adapted for performing epitaxial silicon deposition processes as discussed above and illustratively comprises a chamber body 110, and a first inlet port 114, a second inlet port 170, and an exhaust port 118 disposed about a substrate support 124. The first inlet port 114 and the exhaust port 118 are disposed on opposing sides of the substrate support 124. The second inlet port 170 is configured with respect to the first inlet port 114 to provide a second process gas at an angle to a first process gas provided by the first inlet port 114. The second inlet port 170 and the first inlet port 114 can be separated by an azimuthal angle 202 of up to about 145 degrees on either side of the chamber, described below with respect to FIG. 2, which illustrates a top view of the process chamber 100. The process chamber 100 further includes support systems 130, and a controller 140, discussed in more detail below.

The chamber body 110 generally includes an upper portion 102, a lower portion 104, and an enclosure 120. The upper portion 102 is disposed on the lower portion 104 and includes a lid 106, a clamp ring 108, a liner 116, a baseplate 112, one or more upper lamps 136 and one or more lower lamps 138, and an upper pyrometer 156. In one embodiment, the lid 106 has a dome-like form factor, however, lids having other form factors (e.g., flat or reverse curve lids) are also contemplated. The lower portion 104 is coupled to a first inlet port 114, a second inlet port 170 and an exhaust port 118 and comprises a baseplate assembly 121, a lower dome 132, the substrate support 124, a pre-heat ring 122, a substrate lift assembly 160, a substrate support assembly 164, one or more upper lamps 152 and one or more lower lamps 154, and a lower pyrometer 158. Although the term “ring” is used to describe certain components of the process chamber, such as the pre-heat ring 122, it is contemplated that the shape of these components need not be circular and may include any shape, including but not limited to, rectangles, polygons, ovals, and the like.

FIG. 2 depicts a schematic top view of the chamber 100. As illustrated, the first inlet port 114, the second inlet port 170, and the exhaust port 118 are disposed about the substrate support 124. The exhaust port 118 may be disposed on an opposing side of the substrate support 124 from the first inlet port 114 (e.g., the exhaust port 118 and the first inlet port 114 are generally aligned with each other). The second inlet port 170 may be disposed about the substrate support 124, and in some embodiments (as shown), opposing neither the exhaust port 118 or the first inlet port 114. However, the positioning of the second inlet port 170 in FIG. 2 is merely exemplary and other positions about the substrate support 124 are possible as discussed below.

The first inlet port 114 is configured to provide a first process gas over a processing surface of the substrate 125 in a first direction 208. As used herein, the term process gas refers to both a singular gas and a mixture of multiple gases. Also as used herein, the term “direction” can be understood to mean the direction in which a process gas exits an inlet port. In some embodiments, the first direction 208 is parallel to the processing surface of the substrate 125 and generally pointed towards the opposing exhaust port 118.

The first inlet port 114 may comprise a single port wherein the first process gas is provided therethrough (not shown), or may comprise a first plurality of secondary inlets 210. In some embodiments, the number of secondary inlets 210 in the first plurality is up to about 5 inlets, although greater or fewer secondary inlets may be provided (e.g., one or more). Each secondary inlet 210 may provide the first process gas, which may for example be a mixture of several process gases. Alternatively, one or more secondary inlets 210 may provide one or more process gases that are different than at least one other secondary inlet 210. In some embodiments, the process gases may mix substantially uniformly after exiting the first inlet port 114 to form the first process gas. In some embodiments, the process gases may generally not mix together after exiting the first inlet port 114 such that the first process gas has a purposeful, non-uniform composition. Flow rate, process gas composition, and the like, at each secondary inlet 210 may be independently controlled. In some embodiments, some of the secondary inlets 210 may be idle or pulsed during processing, for example, to achieve a desired flow interaction with a second process gas provided by the second inlet port 170, as discussed below. Further, in embodiments where the first inlet port 114 comprises a single port, the single port may be pulsed for similar reasoning as discussed above.

The second inlet port 170 may be substantially similar in design to the first inlet port 114. The second inlet port 170 is configured to provide a second process gas in a second direction 212 different from the first direction 208. The second inlet port 170 may comprise a single port (as schematically shown in FIG. 1). Alternatively, the second inlet port may 170 comprise a second plurality of secondary inlets 214. Each secondary inlet 214 may provide the second process gas, which may for example be a mixture of several process gases. Alternatively, one or more secondary inlets 214 may provide one or more process gases that are different than at least one other secondary inlets 214. In some embodiments, the process gases may mix substantially uniformly after exiting the second inlet port 170 to form the second process gas. In some embodiments, the process gases may generally not mix together after exiting the second inlet port 170 such that the second process gas has a purposeful, non-uniform composition. Flow rate, process gas composition, and the like, at each secondary inlet 210 may be independently controlled. In some embodiments, the second inlet port 170, or some or all of the secondary inlets 214, may be idle or pulsed during processing, for example, to achieve a desired flow interaction with the first process gas provided by the first inlet port 114.

In some embodiments, a relationship between the first direction 208 of the first inlet port 114 and the second direction 212 of the second inlet port 170 can be at least partially defined by an azimuthal angle 202. The azimuthal angle 202 is measured between the first direction 208 and the second direction 212 with respect to a central axis 200 of the substrate support 124. The azimuthal angle 202 may be up to about 145 degrees, or between about 0 to about 145 degrees. In some embodiments, as shown at 204, the azimuthal angle 202 may be less than 90 degrees resulting in a location of the second inlet port 170 that is in a closer proximity to the first inlet port 114 than to the exhaust port 118. In some embodiments, as shown at 206, the azimuthal angle 202 may be greater than 90 degrees resulting in a location of the second inlet port 170 that is in a closer proximity to the exhaust port 118 than to the first inlet port 114. In some embodiments, and as illustrated in FIG. 2, the azimuthal angle 202 is about 90 degrees. The azimuthal angle 202 may be selected to provide a desired amount of cross-flow interaction between the first and second process gases.

In some embodiments, the second direction 212 may be angled with respect to the substrate surface and the first direction 208 is parallel to the substrate surface. In such an embodiment, the azimuthal angle 202 may be up to about 145 degrees. In one specific example (not shown) of such an embodiment, the azimuthal angle is zero degrees. Accordingly, the first and second inlet ports 114, 170 may be disposed in vertical alignment, for example, stacked atop each other or integrated into a single unit. In such embodiments, the first and second directions 208, 212 are still different (even though the azimuthal angle 202 between them is zero degrees) due to the angled orientation of the second direction 212 and the parallel orientation of the first direction 208 with respect the substrate surface. Accordingly, a flow interaction can occur between the first and second process gases.

In some embodiments, the azimuthal angle defines the difference between the first and second directions 208, 212. For example, where the first and second direction 208, 212 are both parallel to the substrate surface, the azimuthal angle 202 is non-zero such that the first and second direction 208, 212 are different, and thus a flow interaction can be achieved.

Returning to FIG. 1, the substrate support assembly 164 generally includes a support bracket 134 having a plurality of support pins 166 coupled to the substrate support 124. The substrate lift assembly 160 comprises a substrate lift shaft 126 and a plurality of lift pin modules 161 selectively resting on respective pads 127 of the substrate lift shaft 126. In one embodiment, a lift pin module 161 comprises an optional upper portion of the lift pin 128 is movably disposed through a first opening 162 in the substrate support 124. In operation, the substrate lift shaft 126 is moved to engage the lift pins 128. When engaged, the lift pins 128 may raise the substrate 125 above the substrate support 124 or lower the substrate 125 onto the substrate support 124.

The substrate support 124 further includes a lift mechanism 172 and a rotation mechanism 174 coupled to the substrate support assembly 164. The lift mechanism 172 can be utilized for moving the substrate support 124 along the central axis 200. The rotation mechanism 174 can be utilized for rotating the substrate support 124 about the central axis 200.

During processing, the substrate 125 is disposed on the substrate support 124. The lamps 136, 138, 152, and 154 are sources of infrared (IR) radiation (i.e., heat) and, in operation, generate a pre-determined temperature distribution across the substrate 125. The lid 106, the clamp ring 116, and the lower dome 132 are formed from quartz; however, other IR-transparent and process compatible materials may also be used to form these components.

The support systems 130 include components used to execute and monitor pre-determined processes (e.g., growing epitaxial silicon films) in the process chamber 100. Such components generally include various sub-systems. (e.g., gas panel(s), gas distribution conduits, vacuum and exhaust sub-systems, and the like) and devices (e.g., power supplies, process control instruments, and the like) of the process chamber 100. These components are well known to those skilled in the art and are omitted from the drawings for clarity.

The controller 140 generally comprises a central processing unit (CPU) 142, a memory 144, and support circuits 146 and is coupled to and controls the process chamber 100 and support systems 130, directly (as shown in FIG. 1) or, alternatively, via computers (or controllers) associated with the process chamber and/or the support systems.

The process chamber 100 has been described above but is not intended to be limiting of all possible chambers which may be used with embodiments described herein. For example, the chamber 100 may be configured to include a second exhaust port (not shown). For example, the position of the second exhaust port could be defined by the azimuthal angle 202 similar to how the azimuthal angle 202 defines the relationship between the first and second flow directions 208, 212. In such an example, both the first and second process gases may be flowed from the first inlet port 114 and a flow interaction created by the asymmetry of the first and second exhaust ports with respect to the first inlet port.

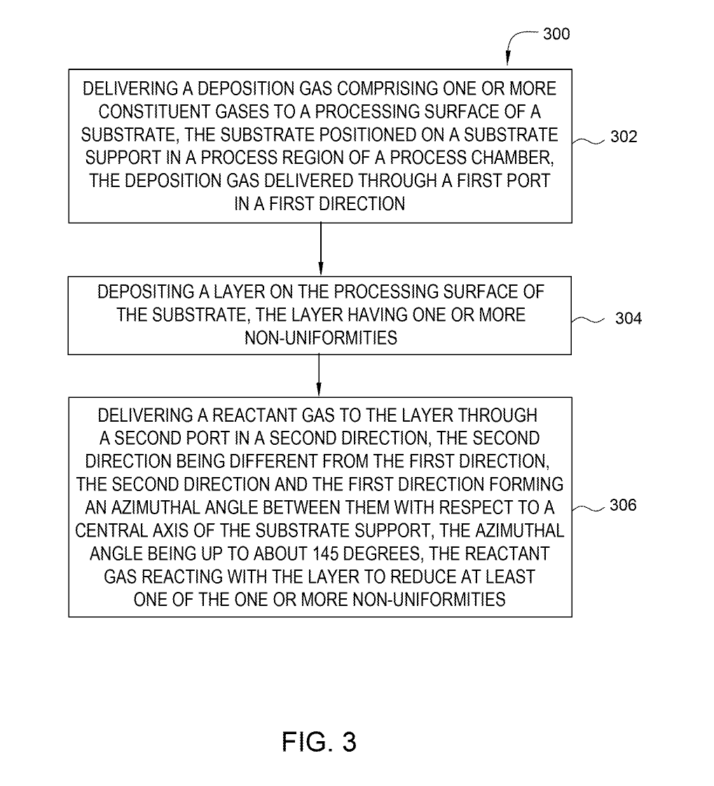

FIG. 3 is a flow diagram of a method 300 for improving uniformity of a layer, according to one embodiment. The layer can be deposited using a deposition gas flow from a first direction and a reactant gas flow from a second direction. The deposition gas as delivered from a first direction can create non-uniformities due to differential flow across the surface of the substrate and due to other factors. By delivering a reactant gas from a second direction to the deposited layer, the non-uniformities of the deposited layer can be improved.

The method 300 begins at 302 by delivering a deposition gas to a processing surface of a substrate. The deposition gas may comprise one or more process gases. The one or more process gases react to deposit a layer on the processing surface. In some embodiments, the first process gas may include one or more deposition gases, and optionally, one or more of a dopant precursor gas, an etchant gas, or a carrier gas. The deposition gas may include a silicon precursor such as at least one of silane (SiH₄), disilane (Si₂H₆), dichlorosilane (H₂SiCl₂). The dopant precursor gas may include one of germane (GeH₄), phosphine (PH₃), diborane (B₂H₆), arsine (AsH₃), or methylsilane (H₃CSiH₃). The carrier gas may include one of nitrogen (N₂), argon (Ar), helium (He), or hydrogen (H₂).

The substrate is positioned on a substrate support in the processing region of a processing chamber. The processing chamber used with one or more embodiments can be any CVD processing chamber capable of delivering gas in a multi directional manner, such as the process chamber 100 described above or chambers from other manufacturers. Flow rates and other processing parameters can vary based on the size of the substrate processed, film type and application and the type of chamber used without diverging from the invention disclosed herein.

A “substrate surface”, as used herein, refers to any substrate or material surface formed on a substrate upon which film processing is performed. For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application. A substrate surface may also include dielectric materials such as silicon dioxide and carbon doped silicon oxides. Substrates may have various dimensions, such as 200 mm, 300 mm or other diameter wafers, as well as rectangular or square panes.

The deposition gas is delivered through a first port in a first direction. The first port can be the first inlet port 114, described with relation to FIGS. 1 and 2. The first port can deliver a gas in a first direction. The first direction is the three dimensional path that the gas will flow out of the first port, assuming an unobstructed path for the gas. The deposition gas and the carrier gas can be introduced into the chamber separately or after combining or premixing the deposition gas and the carrier gas.

A layer is then deposited on the processing surface of the substrate, at element 304. The layer as described herein includes one or multiple elements from the deposition gas. In one embodiment, the deposition gas comprises dichlorosilane, hydrogen chloride (HCl) and phosphine with the layer deposited here being phosphorus doped silicon. The layer can have one or more non-uniformities. Non-uniformities, as used herein, includes portions of the three dimensional structure of the deposited layer, such as edges, bumps, or other formations which affect the uniformity of the layer as deposited. In one example, a non-uniformity is a high edge of the deposited layer.

A reactant gas can then be delivered to the layer through a second port in a second direction, at element 306. The reactant gas is a highly reactive gas as related to the deposited layer. The reactant gas can include hydrogen chloride (HCl), chlorine (Cl₂), fluorine (F₂), hydrogen fluoride (HF) or combinations thereof. The reactant gas can include carrier gases as described above. The reactant gas may be introduced into the process chamber at a flow rate of between about 20 sccm and about 500 sccm for a 300 mm substrate, such as 180 sccm.

The second direction is a direction different from the first direction. The second direction and the first direction form an azimuthal angle between them with respect to a central axis. The azimuthal angle can be up to about 145 degrees. The reactant gas reacts with the layer to diminish at least one of the one or more non-uniformities. The deposition gas and the reactant gas delivery can be performed one or more times and cycles to further control the profile of the deposited layer during deposition. In the case of selective deposition, the reactant gas react with the substrate to remove undesired deposition on certain surfaces/locations of the substrate that require no deposition to improve selectivity.

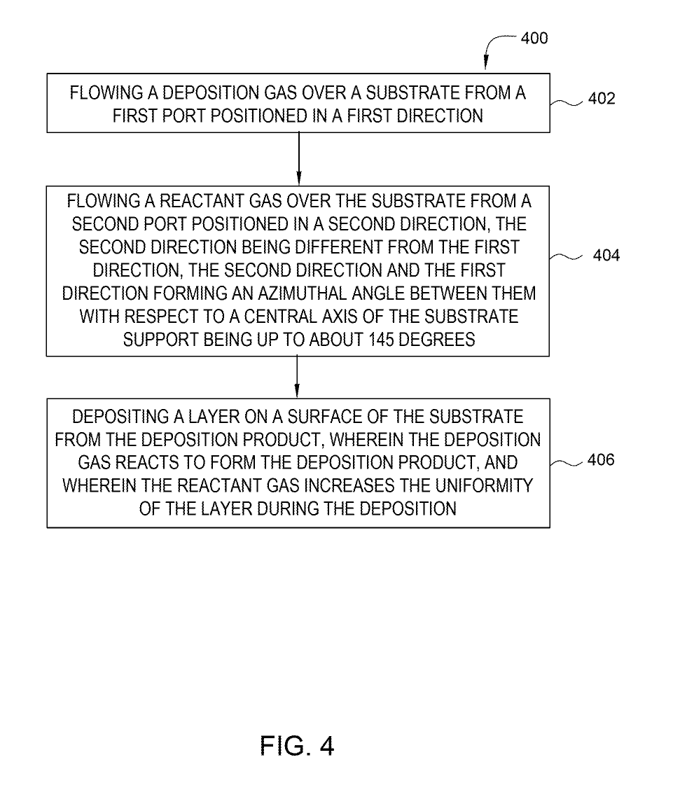

FIG. 4 is a flow diagram of a method 400 for improving uniformity of a layer, according to another embodiment. The layer can be deposited using a deposition gas flow from a first direction and a reactant gas flow from a second direction. The deposition gas, as stated above, can create non-uniformities due to differential flow across the surface of the substrate and/or due to other factors. By delivering a reactant gas from a second direction concurrently with the deposition gas from the first direction during the deposition, the non-uniformities of the deposited layer can be diminished or improved; In the meanwhile, during the deposition, the reactant gas also can interact with the deposition gas and substrate preventing undesired deposition on certain surfaces/locations of the substrate that require no deposition to improve selectivity.

The method 400 begins at element 402 by flowing a deposition gas over a substrate from a first port positioned in a first direction. The deposition gas can be a deposition gas as described with reference to FIG. 3. The first port and the first direction can be a port and direction as described with reference to the figures above.

Concurrent with the deposition gas, a reactant gas can be flowed over the substrate from a second port positioned in a second direction, at element 404. The second direction is different from the first direction. The second direction and the first direction form an azimuthal angle between them with respect to a central axis of the substrate support being up to about 145 degrees. In another embodiment, the azimuthal angle is between 45 degrees and 135 degrees, such as an azimuthal angle of 90 degrees.

A layer is deposited on a surface of the substrate from the deposition product, at element 406. The deposition gas reacts to form the deposition product. The deposition product is the resulting product from the interaction of the deposition gas. Though the reactant gas is present, the reactant gas does not form a deposition product with the deposition gases. It is believed that the reactant gas slows the deposition process by forming reactive intermediaries with the deposition gas and removing high surface area portions of the deposited layer. By slowing the deposition, the deposition products form a more uniform deposition layer. In this way, the reactant gas increases the uniformity of the layer during the deposition through interacting with the deposition gas and affecting the deposition product distribution across the substrate.

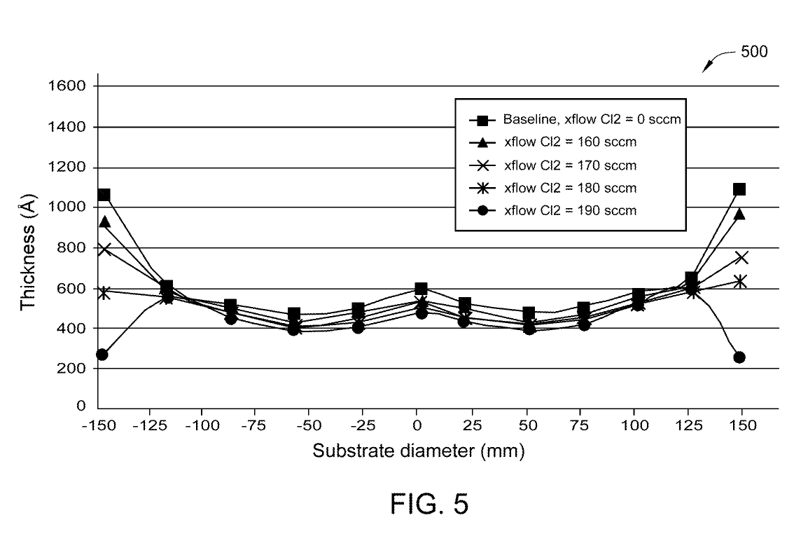

FIG. 5 is a graph 500 depicting improved layer uniformity of silicon-containing layers, deposited according to embodiments described herein. In this graph, silicon substrates received a phosphorus doped silicon layer, deposited as described above. The deposition gas included an N₂ carrier gas, Dichlorosilane, phosphine (10% conc. diluted in hydrogen). The layer was then treated with chlorine (Cl₂) at varying flow rates or no chlorine to establish the baseline uniformity. The X axis depicts the position across the diameter of the substrate in millimeters (mm) and the y axis depicts the thickness of the deposited layer in angstroms (Å).

The first substrate is the control or baseline, as it received no Cl₂. The edges of the deposited layer (approximately 1100 Å) were significantly higher than the center region (approximately 400-600 Å) with a slight peak in the center (approximately 600 Å).

The second substrate received a cross flow of 160 sccm of Cl₂. The edges of the deposited layer (approximately 1000 Å) were still higher becoming more uniform with the center region (approximately 400-600 Å) with a slight peak in the center (approximately 600 Å).

The third substrate received a cross flow of 170 sccm of Cl₂. The edges of the deposited layer (approximately 800 Å) were still higher than the center region (approximately 400-550 Å) with a slight peak in the center (approximately 550 Å).

The fourth substrate received a cross flow of 180 sccm of Cl₂. The edges of the deposited layer (approximately 580 Å) were largely uniform with the center region (approximately 400-550 Å) with a slight peak in the center (approximately 550 Å).

The fifth substrate received a cross flow of 190 sccm of Cl₂. The edges of the deposited layer (approximately 250 Å) were significantly lower the center region (approximately 400-500 Å) with a slight peak in the center (approximately 500 Å).

As shown here, the cross flow of Cl₂ was capable of specifically removing high surface area non-uniformities from the deposited layer without affecting other areas. As the Cl₂ concentration was increased, the non-uniformities of the resulting deposited layer were diminished.

While the foregoing is directed to embodiments of the present invention, other and further embodiments of the invention may be devised without departing from the basic scope thereof, and the scope thereof is determined by the claims that follow.

1. A method for depositing a layer, sequentially comprising:
delivering a deposition gas comprising one or more constituent gases to a processing surface of a substrate, the substrate positioned on a substrate support in a process region of a process chamber, the deposition gas delivered through a first port in a first direction;
depositing a layer on the processing surface of the substrate from the deposition gas, the layer having one or more non-uniformities; and
delivering a reactant gas to the layer through a second port in a second direction, the second direction being different from the first direction, the second direction and the first direction forming an azimuthal angle between them with respect to a central axis of the substrate support being up to about 145 degrees, the reactant gas reacting with the layer to diminish at least one of the one or more non-uniformities, wherein the reactant gas does not form a deposition product with the deposition gas.

2. The method of claim 1, wherein the reactant gas is chlorine (Cl₂)

3. The method of claim 1, wherein the azimuthal angle is between approximately 45 degrees and approximately 135 degrees.

4. The method of claim 1, wherein the deposition gas and the reactant gas intersect at the substrate.

5. The method of claim 1, wherein the delivering the deposition gas, depositing the layer and delivering the reactant gas is repeated one or more times.

6. The method of claim 1, wherein the deposition gas comprises dichlorosilane, phosphine and hydrogen chloride (HCl).

7. The method of claim 1, wherein the reactant gas is delivered to the layer one or more times.

8. A method for depositing a layer, sequentially comprising:
flowing a deposition gas over a substrate from a first port positioned in a first direction;
concurrently flowing a reactant gas while flowing the deposition gas over the substrate from a second port positioned in a second direction, the second direction being different from the first direction, the second direction and the first direction forming an azimuthal angle between them with respect to a central axis of the substrate support being up to about 145 degrees, wherein the reactant gas does not form a deposition product with the deposition gas; and
depositing a layer on a surface of the substrate from a deposition product, wherein the deposition gas reacts to form the deposition product, and wherein the reactant gas increases the uniformity of the layer during the deposition without forming the deposition product.

9. The method of claim 8, wherein the reactant gas is chlorine (Cl₂)

10. The method of claim 8, wherein the azimuthal angle is between approximately 45 degrees and approximately 135 degrees.

11. The method of claim 10, wherein the deposition gas and the reactant gas intersect at the substrate.

12. The method of claim 8, wherein the delivering the deposition gas, depositing the layer and delivering the reactant gas is repeated one or more times.

13. The method of claim 8, wherein the deposition gas comprises dichlorosilane and phosphine.

14. The method of claim 8, wherein the layer is a silicon-containing layer.

15. A method for depositing a layer, sequentially comprising:
delivering a deposition gas comprising dichlorosilane and phosphine to a processing surface of a substrate, the substrate positioned on a substrate support in a process region of a process chamber, the deposition gas delivered through a first port in a first direction;
depositing a silicon-containing layer from the deposition gas on the processing surface of the substrate, the silicon-containing layer having one or more non-uniformities; and
delivering chlorine (Cl₂) to the silicon-containing layer formed on the substrate, the chlorine delivered through a second port in a second direction, the second direction and the first direction forming an azimuthal angle between them with respect to a central axis of the substrate support being between about 45 degrees and about 145 degrees, the chlorine reacting with the silicon-containing layer to diminish at least one of the one or more non-uniformities, wherein the Cl₂ does not form a deposition product with the deposition gas.

16. The method of claim 15, wherein the reactant gas is chlorine (Cl₂)

17. The method of claim 15, wherein the azimuthal angle is between approximately 45 degrees and approximately 135 degrees.

18. The method of claim 15, wherein the delivering the deposition gas, depositing the layer and delivering the reactant gas is repeated one or more times.

19. The method of claim 15, wherein the reactant gas is delivered to the layer one or more times.

20. The method of claim 15, wherein the deposition gas and the reactant gas intersect at the substrate.
